(19) United States
(12) Patent Application Publication
(10) Pub. No.: US 2015/0305146 A1
(43) Pub. Date: Oct. 22, 2015

(54) STRETCHABLE FLEXIBLE SUBSTRATE AND PRODUCTION METHOD FOR THE SAME

(71) Applicant: Panasonic Intellectual Property Management Co., Ltd., Osaka (JP)

(72) Inventor: YOSHIHIRO TOMITA, Osaka (JP)

(21) Appl. No.: 14/678,003

(22) Filed: Apr. 3, 2015

(30) Foreign Application Priority Data
Apr. 21, 2014 (JP) 2014-087535

(51) Int. Cl. H05K 1/02; H05K 3/22; B29C 71/02; B29C 53/32

(52) U.S. Cl. CPC H05K 1/0283; B29C 53/32; H05K 3/22; B29C 71/02; H05K 1/0281; B29L 2031/711

(57) ABSTRACT

A stretchable flexible substrate includes a film base. At least a portion of the film base includes a rolled part. The rolled part includes a first curved part having a curved shape in which the film base is folded back with one main surface of the film base facing inward, a second curved part having a curved shape in which the film base is folded back with another main surface of the film base facing inward, and a base layered part located outside the first curved part and the second curved part. The base layered part has a shape in which the film base is rolled in such a way that a portion of the film base that is contiguous with the first curved part and another portion of the film base that is contiguous with the second curved part are layered on one another.

### BACKGROUND

1. Technical Field

The present disclosure relates to a stretchable flexible substrate including film base and a production method for the same.

2. Description of the Related Art

As electronic devices have decreased in size and thickness, flexible substrates are finding uses in various kinds of electronic equipment. A flexible substrate having a thin profile as a whole has pliability. Thus, a flexible substrate is often used being bent for space saving.

Nowadays, flexible substrates are expected find further applications and their usage in various fields other than the field of general electronic equipments is being studied.

For example, there has been a shift of application from mobile devices carried by persons such as smartphones to wearable devices. Thus, wearing comfort or design conforming to the user's movement is increasingly valued. Flexible substrates used for these devices are required to be not only pliable but also stretchable.

As another example, the functions of a wrist watch as a mobile device that displays time have not been related to the user's movement and the electronic circuitry of such a mobile device has not required flexibility. These years have seen development of bracelet-type activity sensors and like equipment, which are increasingly used in sports and fitness. These devices are designed for use in contact with the human body for sensing or designed to be comfortably attached to a junction or a movable part other than the wrist. Thus pliability as well as stretchability is required of a flexible substrate for interconnecting electronic circuits. Japanese Unexamined Patent Application Publication No. 6-97621 discloses a mounting structure for electronic components that uses a flexible substrate.

### SUMMARY

One non-limiting and exemplary embodiment provides a flexible substrate having stretchability and a production method for the same.

In one general aspect, the techniques disclosed here feature a stretchable flexible substrate including film base. At least a portion of the film base comprises a rolled part. The rolled part includes a first curved part having a curved shape in which the film base is folded back with one main surface of the film base facing inward, a second curved part having a curved shape in which the film base is folded back with another main surface of the film base facing inward, and a base layered part located outside the first curved part and the second curved part. The base layered part has a shape in which the film base is rolled in such a way that a portion of the film base that is contiguous with the first curved part and another portion of the film base that is contiguous with the second curved part are layered on one another. The rolled part has tensile spring against a direction to unroll the base layered part.

The flexible substrate according to an embodiment of the present disclosure has not only pliability but also stretchability.

It should be noted that general or specific embodiments may be implemented as a substrate, an element, a device, a system, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a perspective view schematically showing the structure of a stretchable flexible substrate according to an embodiment of the present disclosure that uses insulating film as film base;

FIG. 2 is a cross-sectional view schematically showing the structure of a stretchable flexible substrate according to an embodiment of the present disclosure that uses metal film as the film base;

FIG. 3 is a cross-sectional view schematically showing the structure of the stretchable flexible substrate according to an embodiment of the present disclosure;

FIGS. 4A to 4D are perspective views schematically illustrating the extension properties of the stretchable flexible substrate according to an embodiment of the present disclosure: FIG. 4A shows the initial state before being stretched, FIG. 4B shows a state in which force to stretch has started to be applied, FIG. 4C shows a state in which the stretching force continues to be applied, and FIG. 4D shows a state in which stretching is completed;

FIG. 5 schematically illustrates the stretchability of the stretchable flexible substrate according to an embodiment of the present disclosure;

FIG. 6 shows a perspective view and a cross-sectional view schematically showing the structure of a stretchable flexible substrate according to an embodiment of the present disclosure in which a conductor layer is buried in insulating film;

FIG. 7 is a perspective view schematically showing the structure of a stretchable flexible substrate according to an embodiment of the present disclosure in which a circuit module is coupled to each end of insulating film;

FIG. 8 is a cross-sectional view schematically showing the structure of the stretchable flexible substrate according to a first embodiment of the present disclosure;

FIG. 9 is a cross-sectional view schematically showing the structure of the stretchable flexible substrate according to a second embodiment of the present disclosure;

FIG. 10 is a cross-sectional view schematically showing the structure of the stretchable flexible substrate according to a third embodiment of the present disclosure;

FIG. 11 is a cross-sectional view schematically showing the structure of the stretchable flexible substrate according to a fourth embodiment of the present disclosure;

FIG. 12 is a cross-sectional view schematically showing the structure of the stretchable flexible substrate according to a fifth embodiment of the present disclosure;

FIGS. 13A and 13B are cross-sectional views schematically showing the structure of the stretchable flexible substrate according to a sixth embodiment of the present disclosure: FIG. 13A shows a state in which reinforcer and a core member are not disposed, and FIG. 13B shows a state in which reinforcer and a core member are disposed;

FIG. 14 is a cross-sectional view schematically showing the structure of the stretchable flexible substrate according to a seventh embodiment of the present disclosure;

FIGS. 15A to 15C are perspective views schematically illustrating the steps of the production method for a stretchable flexible substrate according to an embodiment of the present disclosure; and

FIG. 16 schematically illustrates a variation of first and second columnar members used in step (ii).

### DETAILED DESCRIPTION

### (Underlying Knowledge Forming Basis of the Present Disclosure)

Requirements for flexible substrates have been increasingly demanding in these years. However, as conventional flexible substrates have pliability or bendability but are not stretchable, they are not always satisfactory solutions to the present needs. The present inventor has conceived the present disclosure after closely studying matters relating to the flexibility and stretchability of printed boards and circuit boards. Thus, they will be discussed before describing the present disclosure.

A conventional flexible printed board typically has a structure in which a copper foil pattern for electrically connecting between electronic circuits is held on resin film by adhesion. For protection of the copper foil pattern, resin film called cover lay is often formed on the copper foil.

Since conventional flexible printed boards of this type are based on resin film having flexibility such as polyimide film, they are bendable and have flexibility in the bending direction. They do not however have sufficient stretchability in the direction parallel to the main surface of the resin film (i.e. main surface parallel direction). For example, the percentages of their elongation are about several percent at most.

While resin materials having some pliability and stretchability exist, copper foil cannot have stretchability in itself. Accordingly, if a material with high pliability is used as the resin film, stress generated when the flexible printed board extends or contracts directly acts on the copper foil to cause breakage of the copper foil pattern. This problem necessitates use of material with low stretchability, such as polyimide film, as the substrate material at present.

Since a high expansion and contraction ratio in the main surface parallel direction cannot be obtained with a typical flexible printed board, a flexible printed board folded like a bellows to provide an improved expansion and contraction ratio can be used. The expansion and contraction ratio can be increased by means of a bellows structure, but the expansion and contraction ratio that can be achieved depends on the width and number of folds that permit accommodation into an allocated space. The number of folds can be increased as the radius of curvature of the folded portion is decreased. However, with a small radius of curvature, stress generated by extension concentrates at the single point of the folded portion, possibly causing a breakage of the copper foil pattern.

As the present disclosure has been conceived also in light of these considerations, provision of a flexible substrate having stretchability by the present disclosure is based on a new approach rather than being on the lines of conventional arts.

A stretchable flexible substrate according to one aspect of the present disclosure includes a film base. At least a portion of the film base includes a rolled part. The rolled part includes a first curved part having a curved shape in which the film base is folded back with one main surface of the film base facing inward, a second curved part having a curved shape in which the film base is folded back with another main surface of the film base facing inward, and a base layered part located outside the first curved part and the second curved part. The base layered part has a shape in which the film base is rolled in such a way that a portion of the film base that is contiguous with the first curved part and another portion of the film base that is contiguous with the second curved part are layered on one another. The rolled part has tensile spring against a direction to unroll the base layered part.

The first curved part and the second curved part may have a common portion. The first curved part and the second curved part may thereby be contiguous to each other.

The first curved part and the second curved part may be arranged in point symmetry about an axis of rolling of the rolled part in a sectional plane perpendicular to the axis.

A curvature of the first curved part may be different from the curvature of the second curved part.

The stretchable flexible substrate may further include a first reinforcer disposed on the one main surface of the first curved part, and a second reinforcer disposed on the other main surface of the second curved part.

The stretchable flexible substrate may further include a first core member and a second core member. The first core member may be disposed such that the one main surface makes contact with a body of the first core member in the first curved part, and the second core member may be disposed such that the other main surface makes contact with the body of the second core member in the second curved part.

The stretchable flexible substrate may further include a filler with which a gap is filled. The gap may be defined inside the rolled part by the curved shapes of the first curved part and the second curved part.

The film base may be an insulating film or a metal film.

The film base may be the insulating film, and the stretchable flexible substrate may include a conductor layer provided in the insulating film.

The conductor layer may be buried in the insulating film.

The stretchable flexible substrate may further include a rigid member coupled to the film base, and an electronic element provided on the rigid member. The stretchable flexible substrate may further include an electronic element provided on the film base.

At least portion of the film base may include a plurality of the rolled parts.

The plurality of the rolled parts may be two rolled parts, and the two rolled parts may be in contact with each other due to the tensile springs.

A production method for a stretchable flexible substrate according to another aspect of the present disclosure includes the steps of: (i) preparing a film base; (ii) disposing a first column on one main surface of the film base and disposing a second column on another main surface of the film base so that the first column and the second column are positioned opposite each other across the film base; and (iii) rotating the first column and the second column so that at least a portion of the film base is rolled, thereby forming a rolled part including a first curved part and a second curved part which are curved such that the film base is partially folded back. In the step (iii), the first column and the second column are rotated in a synchronized manner while maintaining a relative positional relationship between the first column and the second column.

In the step (iii), heat treatment may be applied to the film base after rotating the first column and the second column so as to form the rolled part including the first curved part and the second curved part.

Each of the first column and the second column used in the step (ii) may have a cylinder shape, and the first column and the second column may have equal diameter dimensions.

Each of the first column and the second column used in the step (ii) may have a cylinder shape, and the first column and the second column may have different diameter dimensions.

The film base prepared in the step (i) may be an insulating film or a metal film.

The film base in the step (i) may be the insulating film, and a conductor layer may be formed in the insulating film in the step (i).

In the step (i), the conductor layer may be buried in the insulating film by stacking insulating sub-films and the conductor layer with the conductor layer sandwiched between the insulating sub-films.

The film base used in the step (i) may have an elongated shape as a whole.

In step (ii), a first reinforcer may be interposed between the one main surface of the film base and the first column when the first column is disposed on the one main surface of the film base, and a second reinforcer may be interposed between the other main surface of the film base and the second column when the second column is disposed on the other main surface of the film base.

The production method for a stretchable flexible substrate may further include the step of filling the rolled part with filler by feeding filler in a gap defined inside the rolled part by the first curved part and the second curved part.

### [Stretchable Flexible Substrate According to the Present Disclosure]

A stretchable flexible substrate according to an embodiment of the present disclosure will now be described with reference to drawings. Note that various elements shown in the drawings are merely schematic illustrations for facilitating understanding of the present disclosure and the dimensional ratio and/or the outer appearance may differ from the real products.

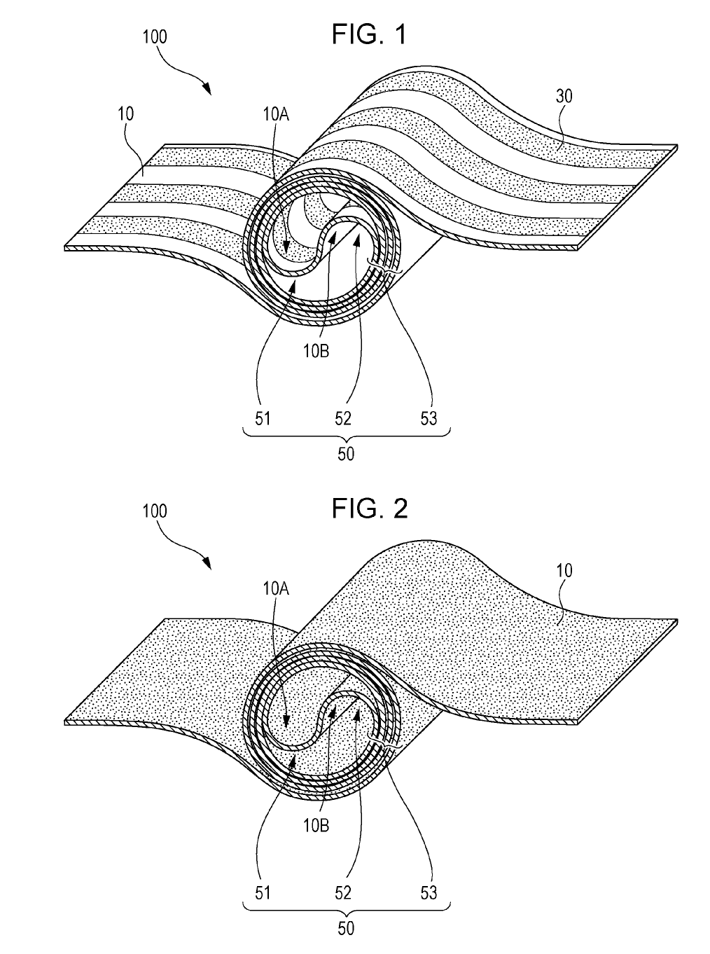

FIGS. 1 to 3 schematically illustrate a stretchable flexible substrate 100 according to the present disclosure. The stretchable flexible substrate 100 according to the present disclosure includes film base 10. With the stretchable flexible substrate 100 in the embodiment shown in FIG. 1, the film base 10 is insulating film and a conductor layer 30 is formed on the insulating film. With the stretchable flexible substrate 100 in the embodiment shown in FIG. 2, in contrast, the film base 10 is metal film. As depicted in FIGS. 1 and 2, the film base 10 is a primary component that constitutes the overall geometry of the stretchable flexible substrate 100.

When the film base 10 is formed from insulating film, the conductor layer 30 provided on or in the film base 10 is a layer having electrical conductivity. The conductor layer 30 may be a patterned layer. For example, the conductor layer 30 may be a wiring layer, which can form conductor circuitry.

The stretchable flexible substrate 100 according to the present disclosure includes a rolled part 50. As depicted, in the rolled part 50, the film base 10 is rolled. That is, the film base 10 is shaped so that a portion of it is rolled like a spiral. The overall appearance of the rolled part 50 is in the shape of a cylinder, for example, as shown in FIGS. 1 and 2.

In the rolled part 50, two curved parts formed by the film base 10 are provided and also a base layered part lies outside them. More specifically, a first curved part 51 and a second curved part 52 that have curved contours formed by the film base 10 being folded back are provided, and also a base layered part 53 formed of overlapping layers of the film base 10 lies outside them.

In other words, the rolled part 50 has the first curved part 51 and the second curved part 52 which are positioned relatively inside and the base layered part 53 which is positioned relatively outside. As will be understood from the illustrated embodiment, because of rolling, the base layered part 53 is structured by the overlapping layers of rolled film base 10, and surrounds the two curved parts 51, 52. In other words, the base layered part 53 is formed by the film base 10 being rolled such that a portion of the film base 10 that is contiguous with the first curved part 51 and another portion of the film base 10 that is contiguous with the second curved part 52 are layered on one another. Being thus structured, the base layered part 53 can contribute to extension and contraction of the substrate in particular as well as preservation of the strength of the rolled part.

The first curved part 51 is curved such that the film base 10 is folded back with one main surface 10A of the film base 10 facing inward, while the second curved part 52 is curved such that the film base 10 is folded back with the other main surface 10B of the film base 10 facing inward. This means that the first curved part 51 and the second curved part 52 are oriented opposite to each other in positional relationship.

As can be seen from the illustrated embodiment, with the stretchable flexible substrate 100 according to the present disclosure, the first curved part 51 and the second curved part 52 are both curved so as to have a round contour as a whole, the orientation of the round portion of the first curved part 51 being opposite to that of the second curved part 52. For their round and curved shapes, the curved parts 51, 52 may also be called “round portions”. Since the first curved part 51 and the second curved part 52 of the present disclosure are evenly rounded in their entirety as described above, stress does not concentrate at a particular point when the stretchable flexible substrate extends or contracts, making it resistant to board or wire breakage.

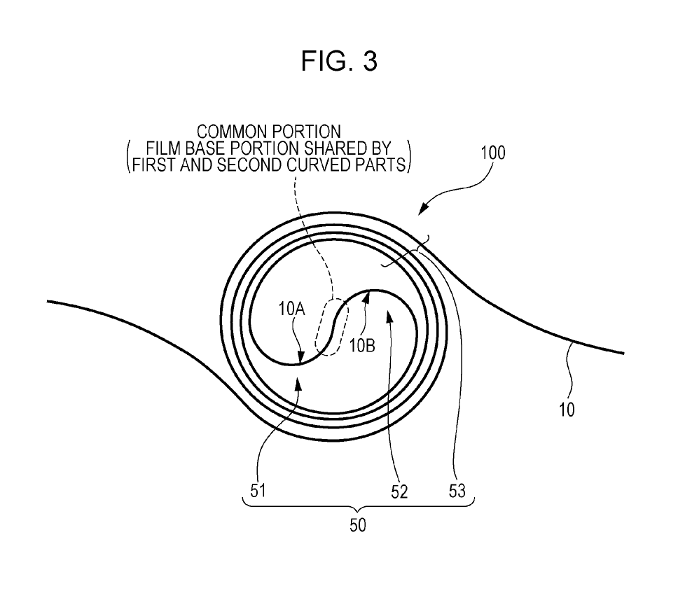

The first curved part 51 and the second curved part 52 may be adjacent to each other in the rolled part 50. That is, the first curved part 51 and the second curved part 52 may be in a side-by-side position relationship in the area inside the base layered part 53 of the rolled part 50. More specifically, as depicted in FIGS. 1 to 3, the portion of the film base that forms the first curved part 51 and the portion of the film base that forms the second curved part 52 may be partially common so that the first curved part 51 and the second curved part 52 are continuous and adjacent to each other. Describing this with the embodiment shown in FIG. 3, the first curved part 51 and the second curved part 52 are provided continuously and adjacent to each other across film base portion 10_{common portion} that is shared by the first curved part and the second curved part. Because of this continuous adjacency, the overall volume of the rolled part is not excessively high despite the presence of the two curved parts. The film base portion 10_{common portion} shared by the first curved part 51 and the second curved part 52 constitutes both a part of the film base portion of the first curved part 51 and a part of the film base portion of the second curved part 52.

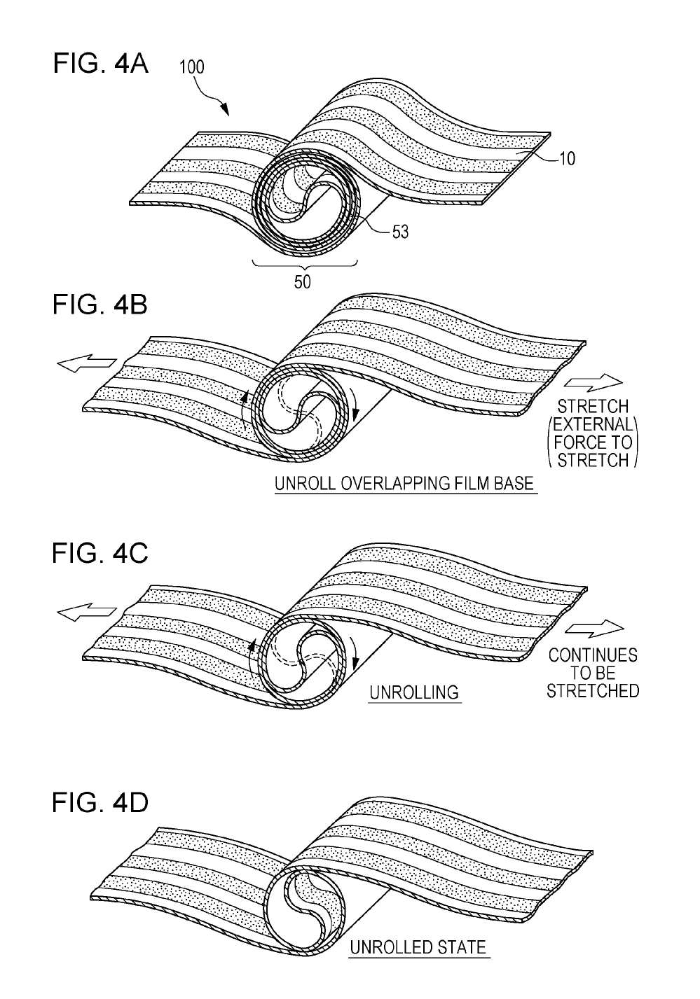

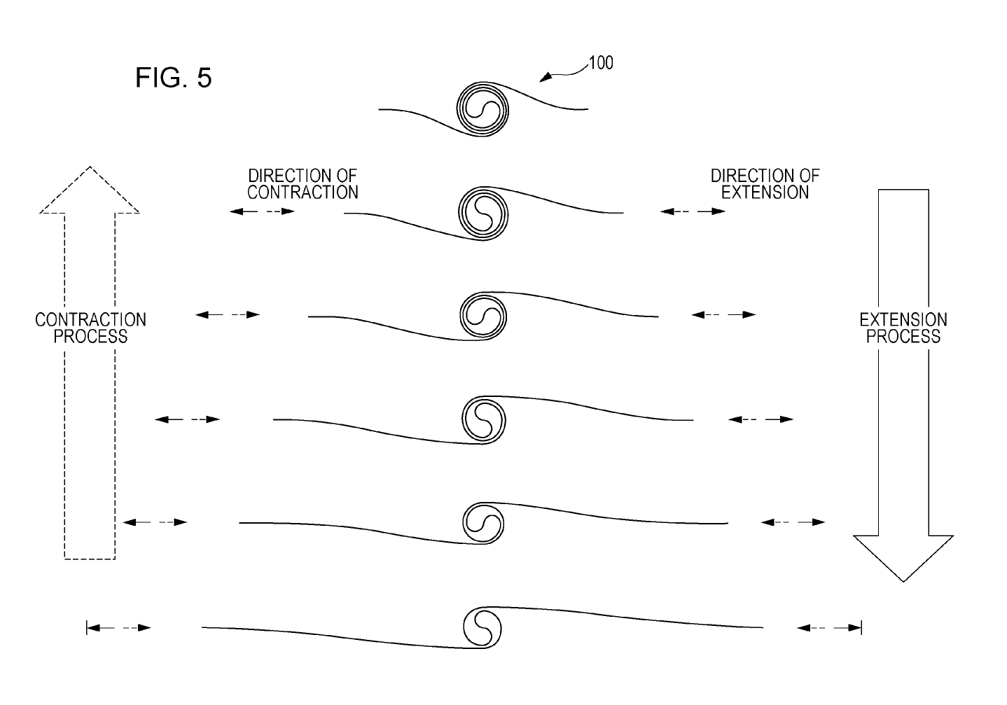

In one particular embodiment of the stretchable flexible substrate 100 according to the present disclosure, when external force to stretch the film base 10 having the rolled part 50 is applied, the film base 10 in a rolled state in the base layered part 53 is unrolled, permitting the film base 10 to be extended in the stretching direction as shown in FIGS. 4A to 4D and 5. That is, in response to unrolling of the base layered part 53, the stretchable flexible substrate 100 extends by the amount by which the base layered part 53 is unrolled. When the external force being applied to the stretched film base 10 is removed, the film base 10 rolls so as to return to the initial rolled state, resulting in contraction of the film base 10. That is, the rolled part 50 has tensile spring against the direction that unrolls the base layered part 53. Stated differently, the rolled part 50 has tensile stress against the external force to unroll the base layered part 53. Since extension and contraction of the stretchable flexible substrate occurs in response to unrolling and restoration of the base layered part 53 as described above, the first curved part 51 and the second curved part 52 are not subjected to large stress during extension and contraction, making the entire stretchable flexible substrate resistant to board or wire breakage.

In the stretchable flexible substrate 100 according to the present disclosure, tension that acts to pull back can be substantially constant and stable. That is, the returning force of a typical coil-shaped spring, for example, increases as the spring is stretched further, whereas the returning force of the stretchable flexible substrate 100 according to the present disclosure does not substantially increase when stretch of the film base 10 advances. Although not restrained by a particular theory, this is because with the stretchable flexible substrate 100 according to the present disclosure, the overlapping layers of rolled film base are merely unrolled by being stretched and the condition for unrolling does not significantly vary in the course of stretching. This property is particularly desirable when considering real products: for example, in application to a product for use in close contact with the human body, such as a wearable device, the stretchable flexible substrate 100 does not fasten too tight when stretched, providing an advantage of stable fit.

The dimension of the stretchable flexible substrate when stretched to the maximum (the maximum extension dimension) is desirably about 150% to 1000% of the dimension in the initial state, more desirably about 300% to 800%, and still more desirably about 400% to 600%, for example. Since the maximum extension dimension of the stretchable flexible substrate 100 according to the present disclosure can be increased as the number of turns of the film base in the base layered part 53 increases, there is substantially no limitation on the maximum extension dimension. Thus, the stretchable flexible substrate 100 according to the present disclosure can provide a desired expansion and contraction ratio in accordance with the application.

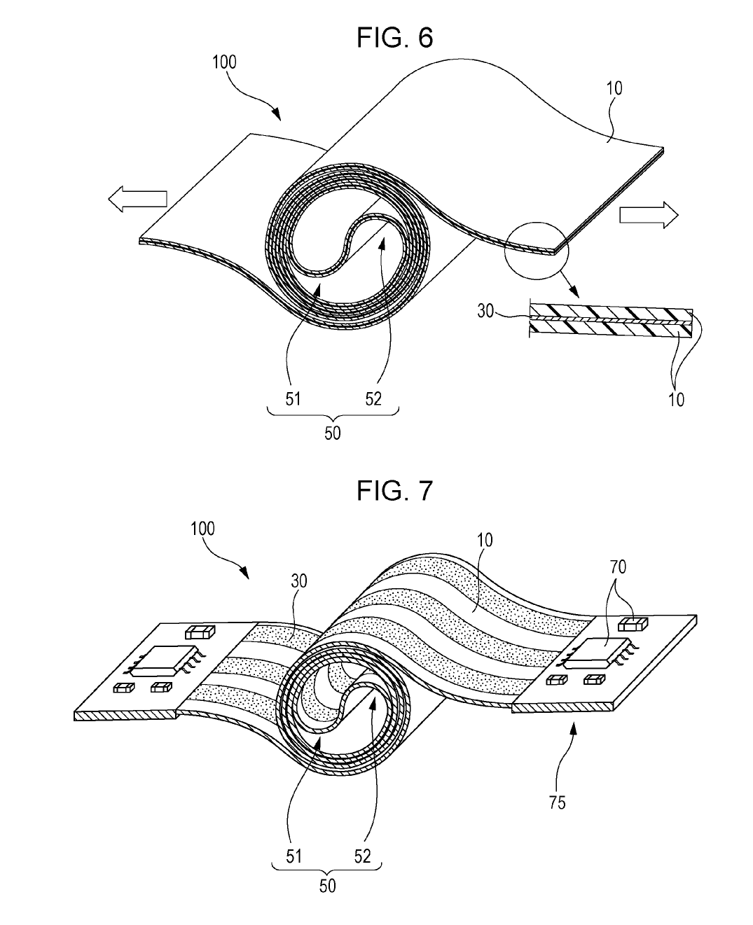

In one embodiment of the stretchable flexible substrate 100 according to the present disclosure, the film base 10 is formed of insulating film and the insulating film has the conductor layer 30 as shown in FIG. 1. In such an embodiment, the conductor layer may be formed to be buried in the insulating film. That is, the conductor layer 30 may extend inside the insulating film 10 as depicted in FIG. 6, in which case stress acting on the conductor layer 30 can be decreased, reducing the possibility of wire or board breakage. More specifically, when the conductor layer 30 is buried in the insulating film 10, part of stress generated by bending or curving of the insulating film 10 could be absorbed by the insulating film, so the stress itself eventually acting on the conductor layer 30 can be reduced. This effect can be exerted in the rolled part 50 in particular. In the base layered part 53 and the curved parts 51, 52, the insulating film 10 is bent relatively largely and hence stress occurring in the conductor layer 30 should be large. However, burying the conductor layer 30 in the insulating film 10 can effectively decrease the stress acting on the conductor layer 30.

In an embodiment, the stretchable flexible substrate 100 according to the present disclosure further includes electronic elements. More specifically, electronic elements may be provided on a main surface of the insulating film 10 so as to be electrically connected with the conductor layer 30, for example. Electronic elements may also be provided on a rigid member coupled to the insulating film 10. Electronic elements provided on a rigid member, which may be a rigid substrate for example, are electrically connected with the conductor layer 30 provided in the insulating film 10, for example. In the embodiment shown in FIG. 7, a circuit module 75 with electronic elements 70 arranged thereon is coupled to each end of the insulating film 10.

Various structural requirements for the present disclosure will be described individually below. With the stretchable flexible substrate according to the present disclosure, the film base 10 has a thin profile, specifically has a thickness small enough to be pliable. For example, the specific thickness of the film base 10 is desirably about 5 μm to about 1000 μm, more desirably about 30 μm to about 100 μm.

When the film base 10 is formed from insulating film, the insulating film can function as a supporting member because the conductor layer 30 and/or electronic elements can be provided on it. The insulating film is made of material having electrical insulation property. For example, the insulating film is desirably made of at least one kind of material selected from a group including polyethylene terephthalate (PET), polyethylene naphthalate (PEN), polyether ether ketone (PEEK), polyimide (PI), liquid crystal polymer, and the like. As more specific examples, the insulating film may be made of polyethylene terephthalate (PET), polyethylene naphthalate (PEN), liquid crystal polymer, or the like. For some applications of the stretchable flexible substrate, the insulating film may be made of a transparent material so that the insulating film is transparent with visible light.

In the interest of preserving the shape of the rolled part 50, the insulating film 10 is desirably formed from thermoplastic resin. This is because insulating film 10 formed from thermoplastic resin could appropriately preserve the shape of the rolled part 50 by undergoing heat treatment after the insulating film 10 is rolled. The insulating film 10 may also be thermosetting resin, in which case the shape of the rolled part 50 could be appropriately preserved by causing the insulating film 10 to cure after rolling it.

The film base 10 is not limited to insulating film but may also be metal film, for example, metal foil. More specifically, the effect of high expansion and contraction ratio is still achieved when metal foil having resilience, such as a flat spring, is used as the film base of the present disclosure because the metal foil can be easily drawn out by stretching and rolls back into the rolled part when the tension is weakened. For the metal foil, copper foil may be used, for example.

As noted above, when the film base 10 is formed from insulating film, the insulating film desirably includes the conductor layer 30. The conductor layer 30 typically constitutes wiring or conductor circuitry in a stretchable flexible substrate. The conductor layer 30 may be made of any material that has electrical conductivity. Examples of the material of the conductor layer include metal materials such as gold (Au), silver (Ag), copper (Cu), nickel (Ni), chromium (Cr), cobalt (Co), magnesium (Mg), calcium (Ca), platinum (Pt), molybdenum (Mo), iron (Fe), and/or zinc (Zn), electrically conductive oxide materials such as zinc oxide (ZnO), tin oxide (SnO₂), indium tin oxide (ITO), fluorine-containing tin oxide (FTO), ruthenium oxide (RuO₂), iridium oxide (IrO₂), and/or platinum oxide (PtO₂), or electrically conductive polymer materials such as based on polythiophene and/or polyaniline. The conductor layer 30 may also be formed from metal foil, for example, a layer formed from copper foil (such as a copper foil pattern). The thickness of the conductor layer 30 is desirably in the range of about 10 nm to about 100 μm, more desirably in the range of about 50 nm to about 50 μm, and still more desirably 1 μm to 50 μm. When the conductor layer 30 is provided on the insulating film 10, it may be coated or encapsulated with insulating material.

An “electronic element” used here is, for example, an electronic circuit component on a stretchable flexible substrate. The electronic element accordingly may be any kind of electronic circuit component that is used in the art of general flexible substrates. For instance, the electronic element may be a semiconductor element, a sensor (for example, a sensor for detecting temperature or pressure), or an actuator (for example, an actuator for generating vibration). A “semiconductor element” as used herein is, for example, a light emitting element, a light receiving element, a diode, a transistor, or the like. Other specific examples of the electronic element include an IC (for example, a control IC), an inductor, a capacitor, a power element, a chip resistor, a chip capacitor, a chip varistor, a chip thermistor, a chip-type laminated filter, a connection terminal, and the like.

In a case in which the film base 10 is formed from insulating film, the stretchable flexible substrate according to the present disclosure may further have a via formed through the insulating film. That is, a via functioning as an electrically conductive portion in the thickness portion of the insulating film may be formed. Presence of such a via enables interconnection of conductor layers provided on the main surface of or inside the insulating film. Since conductor layers being connected also include wiring for electronic elements, electrical connection for electronic elements (such as electrical connection passing through both the main surfaces of the insulating film) can be appropriately routed through the via.

More specific embodiments and variations of the stretchable flexible substrate according to the present disclosure will be described below.

### First Embodiment

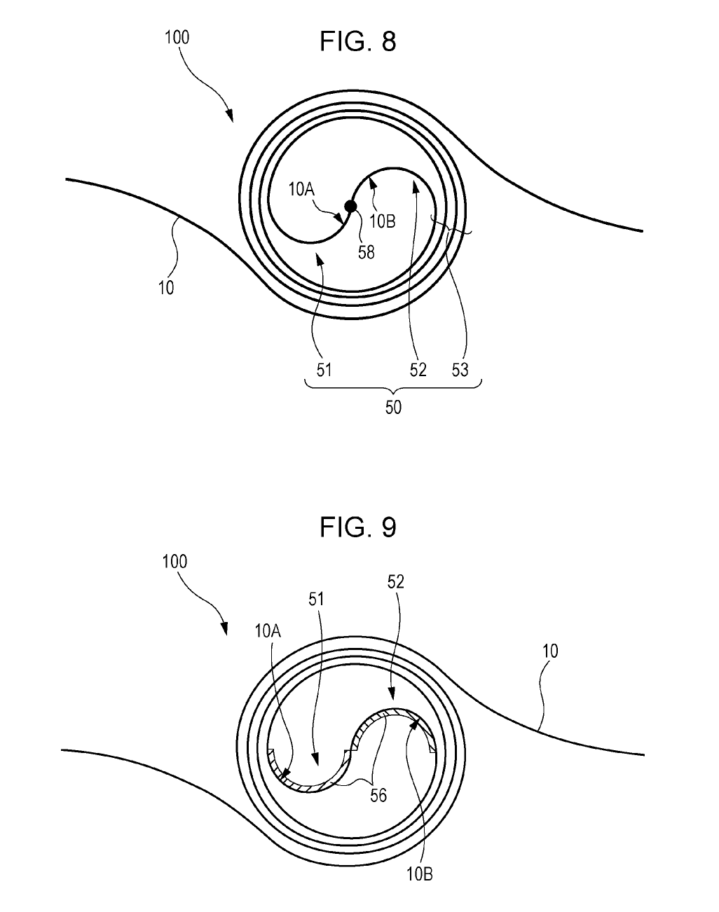

FIG. 8 shows a first embodiment of the stretchable flexible substrate 100 according to the present disclosure. In this embodiment, the first curved part 51 and the second curved part 52 are provided in a symmetrical arrangement inside the base layered part 53 of the rolled part 50. As depicted, the first curved part 51 and the second curved part 52 are in the positional relationship of point symmetry about an axis of rolling 58 in the rolled part 50. When used herein, the “axis of rolling” refers to the axis positioned at the midpoint of the film base portion that is shared by the first curved part and the second curved part. Also, as can be seen from the illustrated embodiment, the axis of rolling can represent the center point of the rolled part when seen in cross section along the thickness direction of the film base.

The first curved part 51 is curved such that the film base 10 is folded back with one main surface 10A of the film base 10 facing inward, while the second curved part 52 is curved such that the film base 10 is folded back with the other main surface 10B of the film base 10 facing inward. The first curved part 51 and the second curved part 52 thus structured have substantially equal curvatures. This means that the first curved part 51 and the second curved part 52 in opposite orientations to each other in positional relationship have substantially the same radius of curvature. As can be understood from the illustrated embodiment, the cross section of the rolled part 50 (that is, the cross section along the thickness direction of the film base or the cross section perpendicular to the axis of rolling 58) has a shape of a so-called “tomoe” (i.e. two interlocking comma-shaped figures), specifically a symmetrical tomoe. Because of this symmetrical arrangement, the stretchable flexible substrate 100 in this embodiment can provide the effect of enhancing the structural strength of the rolled part 50.

### Second Embodiment

FIG. 9 shows a second embodiment of the stretchable flexible substrate 100 according to the present disclosure. In this embodiment, reinforcers 56 are provided on the first curved part 51 and the second curved part 52. The first curved part 51 is curved such that the film base 10 is folded back with one main surface 10A of the film base 10 facing inward, while the second curved part 52 is curved such that the film base 10 is folded back with the other main surface 10B of the film base 10 facing inward. Desirably, the reinforcer 56 is provided both on one main surface 10A of the first curved part 51 and on the other main surface 10B of the second curved part 52.

Addition of the reinforcer 56 enhances the strength of the first curved part 51 and the second curved part 52, making the stretchable flexible substrate 100 more resistant to breakage. For example, at the final stage of unrolling of the base layered part 53 when the film base 10 is stretched, stress tends to concentrate at the curved parts 51, 52, which have the largest curvature. By reinforcing the curved parts 51, 52 which are subjected to large stress with the reinforcer 56, the stretchable flexible substrate 100 becomes more resistant to breakage. In addition, since an area near the curved parts 51, 52 is the center of rotation during unrolling, reinforcement of the curved parts 51, 52 permits smooth unrolling and restoration of the rolled state, thus allowing smooth extension and contraction.

As a non-limiting example, the reinforcer 56 may be in a sheet or film shape as shown in FIG. 9. By way of illustration only, the reinforcer 56 may be a sheet material made of polyimide.

### Third Embodiment

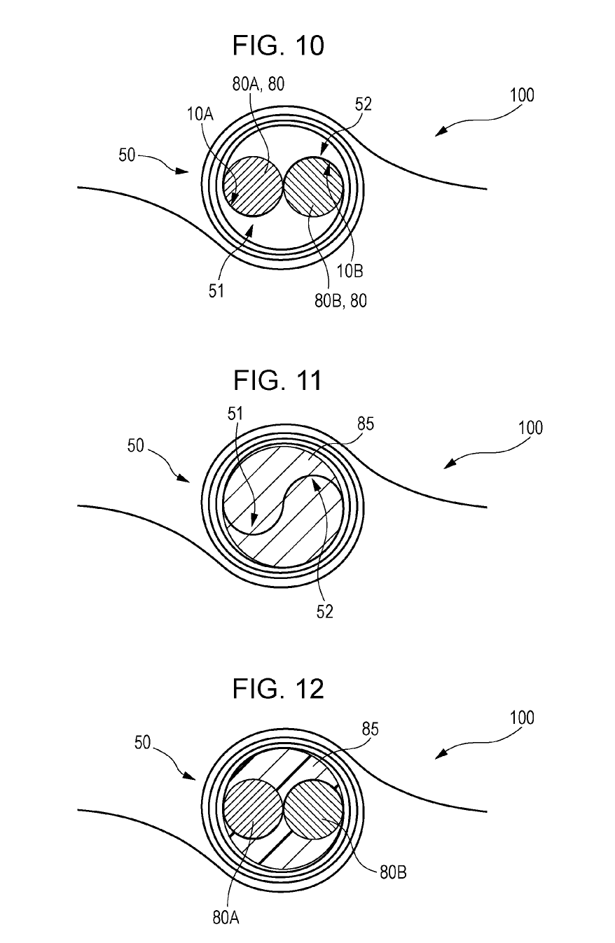

FIG. 10 shows a third embodiment of the stretchable flexible substrate 100 according to the present disclosure. In this embodiment, a core member 80 is provided in the rolled part 50. For example, two core members, a first core member 80A and a second core member 80B, may be provided.

The first core member 80A is desirably disposed such that one main surface 10A of the first curved part 51 makes contact with the body of the first core member 80A. Likewise, the second core member 80B is desirably disposed such that the other main surface 10B of the second curved part 52 makes contact with the body of the second core member 80B. The overall shape of the core members 80A and 80B is desirably cylindrical, though not limited thereto. The core members 80A and 80B can function as shaft members in the rolled part and enables smooth unrolling and restoration of the rolled state, thus allowing smooth extension and contraction.

As will be understood from the embodiment shown in FIG. 10, the core members 80A and 80B can be regarded as the reinforcer 56 in the second embodiment but with an increased thickness. Thus, as with the reinforcer 56, the strength of the first curved part 51 and the second curved part 52 is increased by the core members 80A and 80B, making the stretchable flexible substrate 100 more resistant to breakage.

### Fourth Embodiment

FIG. 11 shows a fourth embodiment of the stretchable flexible substrate 100 according to the present disclosure. In this embodiment, the rolled part 50 is filled with filler 85. Specifically, the filler 85 is desirably provided so as to fill a gap defined inside the rolled part 50 by the bends of the first curved part 51 and the second curved part 52.

As in the second and third embodiments, the filler 85 functions both as reinforcer for the curved parts and as a core member for the rolled part 50. This results in an enhanced strength of the first curved part 51 and the second curved part 52 so that the stretchable flexible substrate 100 becomes more resistant to breakage, and also enables smooth unrolling and restoration of the rolled state, thus allowing smooth extension and contraction.

The filler 85 is desirably made of a material having insulation property, for example, a resin material or inorganic material. When the filler 85 is formed from soft or elastic material (for example, elastomer material), the film base 10 is stretched to the maximum at the final stage of unrolling and extension stops smoothly.

### Fifth Embodiment

FIG. 12 shows a fifth embodiment of the stretchable flexible substrate 100 according to the present disclosure. This embodiment is equivalent to a combination of the third and the fourth embodiments described above: the first core member 80A and the second core member 80B are provided in the rolled part 50 and the rolled part 50 is filled with the filler 85.

In the fifth embodiment, the strength of the first curved part 51 and the second curved part 52 is increased to make the stretchable flexible substrate 100 more resistant to breakage, and also enables smooth unrolling and restoration of the rolled state, thus allowing smooth extension and contraction, as in the third and fourth embodiments.

### Sixth Embodiment

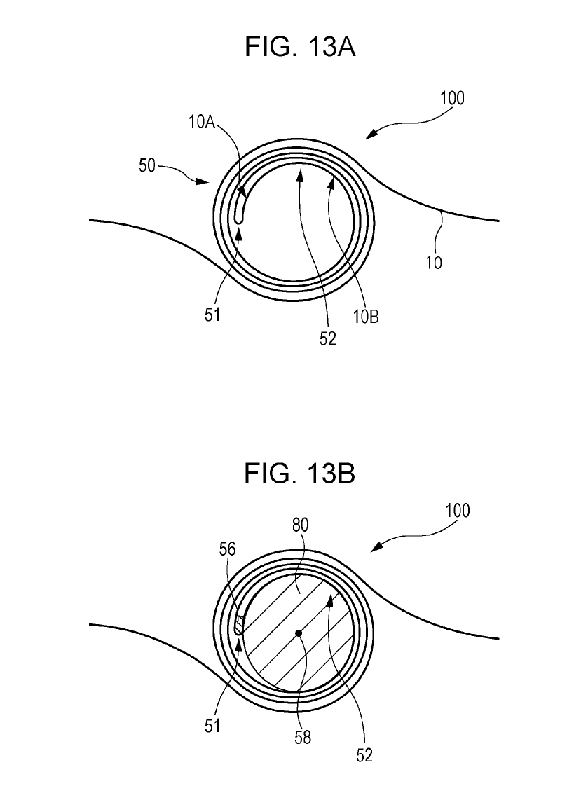

FIGS. 13A and 13B illustrate a sixth embodiment of the stretchable flexible substrate 100 according to the present disclosure. In this embodiment, the curvature of the bend differs between the first curved part 51 and the second curved part 52. More specifically, the first curved part 51 is curved such that the film base 10 is folded back with one main surface 10A of the film base 10 facing inward, while the second curved part 52 is curved such that the film base 10 is folded back with the other main surface 10B of the film base 10 facing inward. The first curved part 51 and the second curved part 52 thus structured have different curvatures. This means that the first curved part 51 and the second curved part 52 in opposite orientations to each other in positional relationship have different radii of curvature. By way of example only, the radius of curvature of the second curved part 52 may be at least twice, desirably at least five times (for example, about six to thirty times) larger than that of the first curved part 51.

In the illustrated embodiment, the curvature of the first curved part 51 is larger than that of the second curved part 52. That is, the radius of curvature of the first curved part 51 is smaller than the radius of curvature of the second curved part 52. As shown in FIG. 13B, as the first curved part 51 has a larger curvature and can generate a relatively larger stress, the first curved part 51 may be provided with reinforcer 56. As also shown in FIG. 13B, as the axis of rolling 58 can be positioned in the gap defined by the bend of the second curved part 52, the core member 80 may be provided in the gap.

### Seventh Embodiment

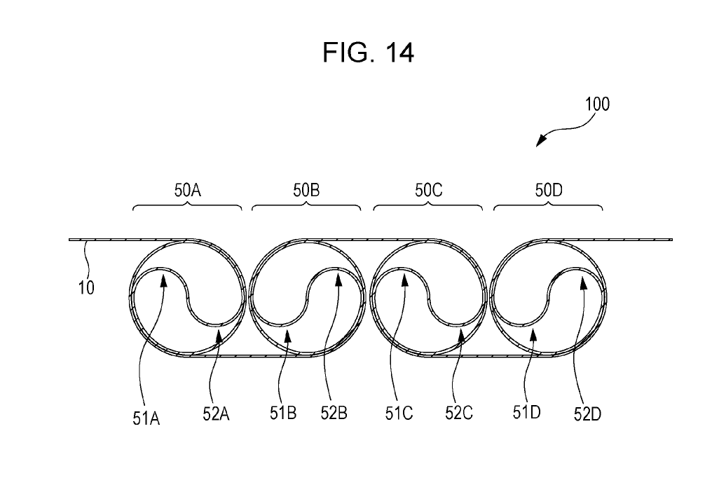

FIG. 14 shows a seventh embodiment of the stretchable flexible substrate 100 according to the present disclosure. In this embodiment, at least two rolled parts are provided. Specifically, at least two rolled parts each having the first curved part and the second curved part are provided. For example, two rolled parts that are in contact with each other due to tensile spring may be provided.

In the illustrated embodiment, four rolled parts 50A, 50B, 50C, and 50D are provided and first curved parts (51A, 51B, 51C, and 51D) and second curved parts (52A, 52B, 52C, and 52D) are formed in them respectively.

This embodiment can increase the maximum extension while keeping an increase in the thickness of the stretchable flexible substrate 100 low. Specifically, if the film base 10 is rolled into only one rolled part in order to increase the maximum extension, the size of the rolled part would become large. In contrast, when the rolled part is divided into multiple sub-rolled parts, the thickness of each sub-rolled part is not significantly large. The seventh embodiment thus can provide a stretchable flexible substrate 100 that is not voluminous as a whole.

### [Production Method for the Stretchable Flexible Substrate According to the Present Disclosure]

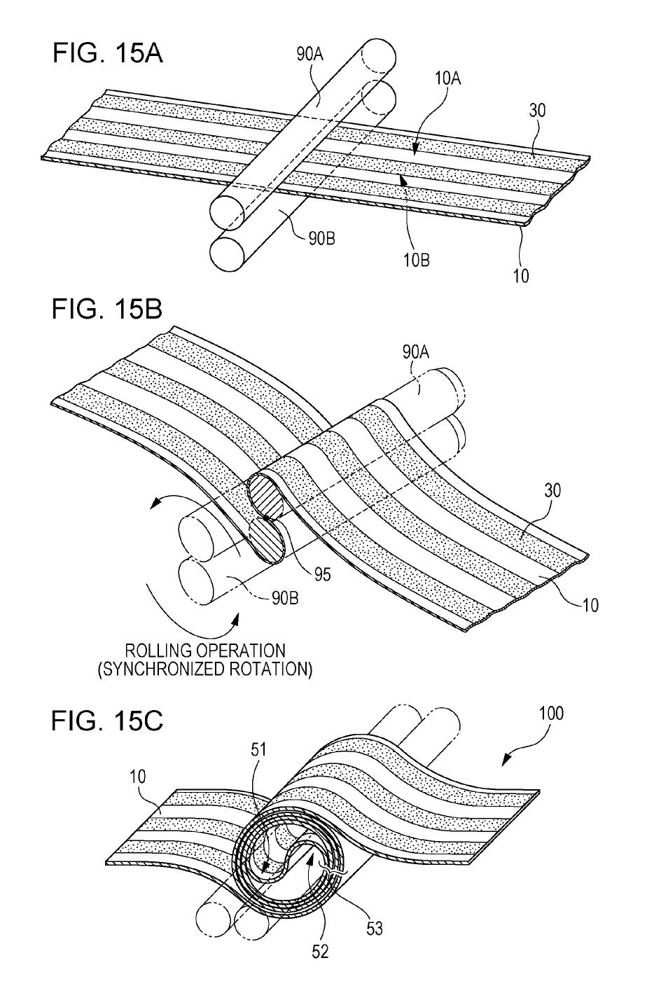

Referring now to FIGS. 15A to 15C, the production method for the stretchable flexible substrate according to the present disclosure will be described. The embodiment shown in FIGS. 15A to 15C concerns a production method for a stretchable flexible substrate that uses insulating film as the film base 10. The following will describe a stretchable flexible substrate that uses insulating film as the film base 10 as a representative example.

The production method according to the present disclosure starts by preparing the film base 10 in step (i). For example, insulating film or metal film is prepared as the film base 10. As insulating film, insulating film made from resin is prepared, for example. By way of example, insulating film made of at least one kind of material selected from a group including polyethylene terephthalate (PET), polyethylene naphthalate (PEN), polyether ether ketone (PEEK), polyimide (PI), liquid crystal polymer, and the like is prepared. As metal film, metal foil is prepared, for example. An example of metal foil is copper foil. The film base prepared in step (i) may be a commercially available film or obtained with a typical film production technique (for example, inflation, T-die, calendering, casting, cutting, emulsion, hot pressing, or vapor deposition).

The film base 10 used in step (i) is desirably in an elongated shape (that is, strip-shaped) overall so that its longitudinal direction coincides with the direction of extension and contraction. This is because the film base 10 in an elongated shape allows a greater number of turns of the film base in the base layered part 53 of the rolled part 50, thus imparting high extension and contraction properties to the stretchable flexible substrate. For facilitating the rolling operation in subsequent step (iii), material partially formed or contoured into a cylindrical shape in advance may be used as the film base 10.

When insulating film is prepared as the film base 10, the conductor layer 30 is desirably formed on the insulating film 10 (see FIG. 15A). With the conductor layer 30, desired wiring or conductor circuitry can be added to the stretchable flexible substrate. The conductor layer 30 may be formed on one main surface and/or the other main surface of the insulating film 10. Alternatively, the conductor layer 30 may be buried in the insulating film 10 (see FIG. 6). A conductor layer can be buried in insulating film by stacking insulating sub-films and the conductor layer with the conductor layer sandwiched between the insulating sub-films.

The method for forming the conductor layer 30 is not limited: it may be formed with any of traditional techniques, for example, printing process, or vacuum deposition or sputtering. As a further example, it may be produced by bonding of metal foil. As a more specific example, metal foil may be bonded to the insulating film 10, which is then subjected to patterning to obtain a desired conductor layer. The thickness of the conductor layer 30 to be formed is desirably about 10 nm to about 100 μm, more desirably about 50 nm to about 50 μm, still more desirably about 1 μm to 50 μm.

In a case in which electronic elements are disposed, the electronic elements may be provided on the insulating film 10. Alternatively, a circuit module 75 with electronic elements 70 arranged thereon may be coupled to each end of the insulating film base 10 (see FIG. 7).

After step (i), step (ii) is performed. In this step, a first columnar member 90A and a second columnar member 90B are arranged as shown in FIG. 15A. Specifically, the first columnar member 90A is disposed on one main surface 10A of the film base 10 and the second columnar member 90B is disposed on the other main surface 10B of the film base 10 so that the first columnar member 90A and the second columnar member 90B are positioned opposite each other across the film base 10. If necessary, the first columnar member 90A and the second columnar member 90B may be bonded to the film base 10.

The first columnar member 90A and the second columnar member 90B are desirably cylinder-shaped members. This facilitates giving a round contour to the overall shapes of the first curved part 51 and the second curved part 52 of the resulting stretchable flexible substrate 100. The first columnar member 90A and the second columnar member 90B may be formed from any material that has strength high enough to permit the rotation operation in step (iii). By way of illustration only, the first columnar member 90A and the second columnar member 90B may be made of metal.

The first columnar member 90A and the second columnar member 90B in a cylindrical shape may have substantially equal diameter dimensions, in which case a stretchable flexible substrate 100 having the first curved part 51 and the second curved part 52 of the same curvature can be finally produced. This means that the first curved part 51 and the second curved part 52 can be placed in a positional relationship of point symmetry about the axis of rolling 58 of the rolled part 50 (see FIG. 8).

The first columnar member 90A and the second columnar member 90B in a cylindrical shape may have different diameter dimensions, however, in which case a stretchable flexible substrate 100 having the first curved part 51 and the second curved part 52 of different curvatures can be finally produced (see FIGS. 13A and 13B).

After step (ii), step (iii) is performed. In this step, rolling operation is performed as shown in FIG. 15B. Specifically, the first columnar member 90A and the second columnar member 90B are rotated so that at least a portion of the film base 10 is rolled. As a result, the first curved part 51 and the second curved part 52 curved such that a part of the film base 10 is folded back can be formed and also the base layered part 53 is formed outside them (see FIG. 15C).

In the rolling operation, the first columnar member 90A and the second columnar member 90B are rotated in a synchronized manner while maintaining the relative positional relationship between the first columnar member 90A and the second columnar member 90B. Stated differently, the first columnar member 90A and the second columnar member 90B are rotated in a synchronized manner about a contact point 95 between the first columnar member 90A and the second columnar member 90B as the axis of rolling. The direction of rotation is not limited: it may either be clockwise or counter-clockwise.

In step (iii), heat treatment is desirably applied in the interest of preserving a desired shape of the rolled part 50. The heat treatment may be done at low temperature or high temperature. Specifically, it is desirable that heat treatment be applied to the film base 10 after rotating the first columnar member 90A and the second columnar member 90B so as to form a rolled part having the first curved part and the second curved part. That is, heat treatment may be performed on the film base 10 in the state of FIG. 15C. In the case of insulating film 10 made of thermoplastic resin for example, the film base 10 can be once softened through the heat treatment and hardened upon being cooled subsequently, so the shape of the rolled part can be appropriately preserved. The temperature and duration of heating may be chosen in accordance with the material of the insulating film 10. For example, for insulating film 10 made of polyethylene terephthalate, the heating temperature is desirably about 90° C. to 160° C., more desirably about 100° C. to 140° C. For these temperatures, the heating time is desirably about 5 to 30 minutes, more desirably about 8 to 15 minutes.

Appropriately preserving the shape of the rolled part by heat treatment and the like imparts more desirable extension and contraction properties to the resulting stretchable flexible substrate. The contraction properties of the stretchable flexible substrate in particular can be improved. Specifically, the stretchable flexible substrate being stretched into an unrolled state returns to the initial rolled state more easily due to preservation of the shape of the rolled part.

Through the steps (i) to (iii) described above, the stretchable flexible substrate 100 can be finally obtained.

After step (iii), the first columnar member 90A and the second columnar member 90B used for the rolling operation may be removed from the film base 10 to produce a stretchable flexible substrate 100 of the structure shown in FIG. 1 or 3. For obtaining a stretchable flexible substrate 100 of a structure such as shown in FIG. 10, however, the first columnar member 90A and the second columnar member 90B may be left on the film base 10. That is, when fabricating a stretchable flexible substrate 100 with the first core member 80A and the second core member 80B contained in the rolled part 50, the first columnar member 90A and the second columnar member 90B used for formation of the rolled part 50 may be used as the first core member 80A and the second core member 80B respectively.

For obtaining a stretchable flexible substrate 100 of a structure such as shown in FIG. 9, the reinforcer 56 is desirably added in step (ii). Specifically, when the first columnar member 90A is disposed on one main surface 10A of the film base 10, the reinforcer 56 is desirably interposed between one main surface 10A of the film base 10 and the first columnar member 90A. Likewise, when the second columnar member 90B is disposed on the other main surface 10B of the film base 10, the reinforcer 56 is desirably interposed between the other main surface 10B of the film base 10 and the second columnar member 90B. This results in a stretchable flexible substrate 100 with the reinforcer 56 added both on one main surface 10A of the first curved part 51 and the other main surface 10B of the second curved part 52.

For obtaining a stretchable flexible substrate 100 of a structure such as shown in FIG. 11, the rolled part is desirably filled with filler. The production method according to the present disclosure accordingly may further include the step of filling the rolled part 50 with filler. Specifically, filler is desirably fed in the gap defined inside the rolled part 50 by the first curved part 51 and the second curved part 52. For example, after removing the first columnar member 90A and the second columnar member 90B used in the rolling operation in step (iii), filler may be desirably fed in the gap defined inside the rolled part 50 by the first curved part 51 and the second curved part 52.

While embodiments of the present disclosure have been described, it will be readily appreciated by those skilled in the art that the present disclosure is not limited to the embodiments and various modifications may be made thereto.

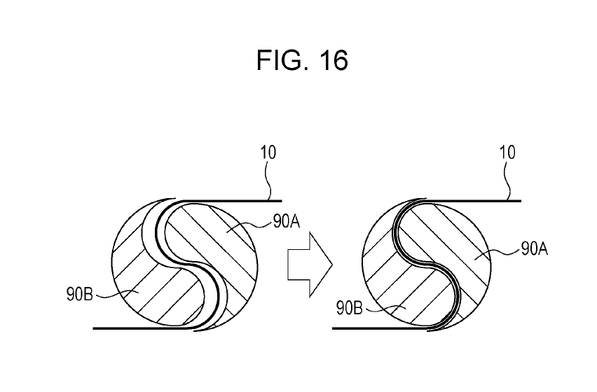

For example, the shape of the first columnar member 90A and the second columnar member 90B used in step (ii) of the production method of the present disclosure is not limited to a cylinder but may be the shape shown in FIG. 16. Specifically, the first columnar member 90A and the second columnar member 90B may also be columnar members forming a so-called “tomoe” (two interlocking comma-shaped figures) in their cross section. The first columnar member 90A and the second columnar member 90B in such a shape facilitate rolling operation because of their complementary contours as depicted. In other words, the first columnar member 90A and the second columnar member 90B can be rotated in a synchronized manner more easily while maintaining the relative positional relationship between the first columnar member 90A and the second columnar member 90B.

The flexible substrate according to the present disclosure has not only pliability but also stretchability. Especially owing to the presence of the first curved part curved such that the film base is folded back with one main surface of the film base facing inward and the second curved part curved such that the film base is folded back with the other main surface of the film base facing inward in the rolled part, the stretchable flexible substrate according to the present disclosure provides desirable extension and contraction properties.

The stretchable flexible substrate according to the present disclosure can be used as a printed board or circuit board having extension and contraction properties and flexibility. It is therefore applicable to such fields as wearable devices, healthcare, medicine, and nursing, in addition to the art of general electronic equipment. For example, for an electronic device required to be stretchable and/or flexibly deform to movements of a human body, such as wearable equipment, the stretchable flexible substrate according to the present disclosure can be used as a printed board having high stretchability for interconnecting circuit modules.

What is claimed is:

1. A stretchable flexible substrate comprising a film base, wherein
at least a portion of the film base comprises a rolled part including:
a first curved part having a curved shape in which the film base is folded back with one main surface of the film base facing inward,
a second curved part having a curved shape in which the film base is folded back with another main surface of the film base facing inward, and
a base layered part located outside the first curved part and the second curved part, the base layered part having a shape in which the film base is rolled in such a way that a portion of the film base that is contiguous with the first curved part and another portion of the film base that is contiguous with the second curved part are layered on one another, and
the rolled part has a tensile spring against a direction to unroll the base layered part.

2. The stretchable flexible substrate according to claim 1, wherein the first curved part and the second curved part have a common portion and thereby the first curved part and the second curved part are contiguous to each other.

3. The stretchable flexible substrate according to claim 1, wherein the first curved part and the second curved part are arranged in point symmetry about an axis of rolling of the rolled part in a sectional plane perpendicular to the axis.

4. The stretchable flexible substrate according to claim 1, wherein a curvature of the first curved part is different from a curvature of the second curved part.

5. The stretchable flexible substrate according to claim 1, further comprising:
a first reinforcer disposed on the one main surface of the first curved part; and
a second reinforcer disposed on the other main surface of the second curved part.

6. The stretchable flexible substrate according to claim 1, further comprising:
a first core member disposed in contact with the one main surface of first curved part; and
a second core member disposed in contact with the other main surface of second curved part.

7. The stretchable flexible substrate according to claim 1, further comprising:
a filler with which a gap is filled, the gap being defined inside the rolled part by the curved shapes of the first curved part and the second curved part.

8. The stretchable flexible substrate according to claim 1, wherein the film base is an insulating film or a metal film.

9. The stretchable flexible substrate according to claim 8, wherein
the film base is the insulating film, and
the stretchable flexible substrate includes a conductor layer provided in the insulating film.

10. The stretchable flexible substrate according to claim 9, wherein the conductor layer is buried in the insulating film.

11. The stretchable flexible substrate according to claim 1, further comprising an electronic element provided on the film base or a rigid member coupled to the film base.

12. The stretchable flexible substrate according to claim 1, wherein at least portion of the film base comprises a plurality of the rolled parts.

13. The stretchable flexible substrate according to claim 12, wherein
the plurality of the rolled parts are two rolled parts, and
the two rolled parts are in contact with each other due to the tensile springs.

14. A production method for a stretchable flexible substrate, comprising the steps of:
(i) preparing a film base;
(ii) disposing a first column on one main surface of the film base and disposing a second column on another main surface of the film base so that the first column and the second column are positioned opposite each other across the film base; and
(iii) rotating the first column and the second column so that at least a portion of the film base is rolled, thereby forming a rolled part including a first curved part and a second curved part which are curved such that the film base is partially folded back, wherein
in the step (iii), the first column and the second column are rotated in a synchronized manner while maintaining a relative positional relationship between the first column and the second column.

15. The production method for a stretchable flexible substrate according to claim 14, wherein in the step (iii), heat treatment is applied to the film base after rotating the first column and the second column so as to form the rolled part including the first curved part and the second curved part.

16. The production method for a stretchable flexible substrate according to claim 15, wherein each of the first column and the second column used in the step (ii) has a cylinder shape, and the first column and the second column have equal diameter dimensions.

17. The production method for a stretchable flexible substrate according to claim 15, wherein each of the first column and the second column used in the step (ii) has a cylinder shape, and the first column and the second column have different diameter dimensions.

18. The production method for a stretchable flexible substrate according to claim 15, wherein the film base prepared in the step (i) is an insulating film or a metal film.

19. The production method for a stretchable flexible substrate according to claim 18, wherein the film base in the step (i) is the insulating film, and a conductor layer is formed in the insulating film in the step (i).

20. The production method for a stretchable flexible substrate according to claim 19, wherein in the step (i), the conductor layer is buried in the insulating film by stacking insulating sub-films and the conductor layer with the conductor layer sandwiched between the insulating sub-films.
